(19) United States
(12) Patent Application Publication
(10) Pub. No.: US 2025/0063714 A1
(43) Pub. Date: Feb. 20, 2025

(54) MEMORY AND MANUFACTURING METHOD THEREFOR

(71) Applicant: BEIJING SUPERSTRING ACADEMY OF MEMORY TECHNOLOGY, Daxing District, Beijing (CN)

(72) Inventors: Zhengyong ZHU, Beijing (CN); Chao ZHAO, Beijing (CN); Bokmoon KANG, Beijing (CN); Guilei WANG, Beijing (CN)

(73) Assignee: BEIJING SUPERSTRING ACADEMY OF MEMORY TECHNOLOGY, Daxing District, Beijing (CN)

(21) Appl. No.: 18/714,798

(22) PCT Filed: Dec. 20, 2022
(86) PCT No.: PCT/CN2022/140430

§ 371 Date: May 30, 2024

(30) Foreign Application Priority Data
Jul. 7, 2022 (CN) 202210803480.X

(51) Int. Cl. H10B 12/00; H01L 27/088; H01L 29/786

(52) U.S. Cl. CPC H10B 12/01; H01L 27/088; H01L 29/78642

(57) ABSTRACT

Provided is a memory. The memory includes: a plurality of memory cells, word lines, and bit lines; wherein each of the memory cells comprises: a first transistor, wherein a first source of the first transistor is electrically connected to the bit line; a second transistor, connected in series to the first transistor; and a capacitor, electrically connected to a second drain of the second transistor. The first transistor and the second transistor are both n-type transistors or p-type transistors, and a first gate of the first transistor and a second gate of the second transistor are electrically connected to the word line.

### CROSS-REFERENCE TO RELATED APPLICATIONS

This application is a U.S. national stage of International Application No. PCT/CN2022/140430, filed on Dec. 20, 2022, which claims priority to Chinese Patent Application No. 202210803480.X, filed on Jul. 7, 2022, the contents of which are incorporated herein by reference in their entireties.

### TECHNICAL FIELD

The present disclosure relates to the technical field of semiconductors, and in particular, to a memory and a method for manufacturing the same.

### BACKGROUND

With the development of semiconductor device integration technology, for a semiconductor device such as a memory, in order to increase a storage density of the memory, memory cells in the memory are becoming smaller and smaller.

### SUMMARY

The present disclosure provides a memory and a method for manufacturing the same, which are at least configured to improve the disadvantages in the prior art

According to some embodiments of the present disclosure, a memory is provided, including: a plurality of memory cells, word lines, and bit lines;
wherein each of the memory cells includes:
a first transistor, wherein a first source of the first transistor is electrically connected to the bit line;
a second transistor, connected in series to the first transistor; and
a capacitor, electrically connected to a second drain of the second transistor;
wherein the first transistor and the second transistor are both n-type transistors or p-type transistors, and a first gate of the first transistor and a second gate of the second transistor are both electrically connected to the word line.

In some embodiments, the first transistor and the second transistor are vertical transistors, and the first transistor and the second transistor are stacked in a direction perpendicular to a base substrate.

In some embodiments, a common electrode is arranged between the first transistor and the second transistor in the direction perpendicular to the base substrate, the first transistor is connected to the second transistor in series through the common electrode, and a first drain of the first transistor and a second source of the second transistor constitute the common electrode.

In some embodiments, the first transistor includes a first semiconductor layer, the second transistor includes a second semiconductor layer; and the first semiconductor layer and the second semiconductor layer are stacked in the direction perpendicular to the base substrate.

In some embodiments, the common electrode is arranged between the first semiconductor layer and the second semiconductor layer in the direction perpendicular to the base substrate, the first gate and the first semiconductor layer are arranged on the same layer, and the second gate and the second semiconductor layer are arranged on the same layer.

In some embodiments, the first gate is arranged around the first semiconductor layer and is insulated from the first semiconductor layer, and the second gate is arranged around the second semiconductor layer and is insulated from the second semiconductor layer.

In some embodiments, each of the first semiconductor layer, the common electrode, and the second semiconductor layer is in a columnar structure, the first source is arranged at one end, away from the common electrode, of the first semiconductor layer or on a circumferential wall of a portion of the first semiconductor layer, and the second drain is arranged at one end, away from the common electrode, of the second semiconductor layer or on a circumferential wall of a portion of the second semiconductor layer.

In some embodiments, orthographic projections of the first semiconductor layer and the second semiconductor layer on the base substrate are within orthographic projections of the first source, the common electrode, and the second drain on the base substrate, and orthographic projections of at least a portion of the first gate and at least a portion of the second gate on the base substrate are within the orthographic projections of the first source, the common electrode, and the second drain on the base substrate.

In some embodiments, the memory cell further includes a connection electrode, arranged around outer sidewalls of the first gate and the second gate, and the first gate and the second gate are both connected to the connection electrode.

In some embodiments, each of the word lines includes a plurality of subsections sequentially connected to each other, wherein each of the subsections is arranged around outer sidewalls of the first gate, the common electrode, the second gate, and the second drain, and a surface of the subsection is flush with a surface, away from the common electrode, of the second drain.

In some embodiments, the first semiconductor layer is arranged around an outer sidewall of the first gate and is insulated from the first gate, and the second semiconductor layer is arranged around an outer sidewall of the second gate and is insulated from the second gate.

In some embodiments, the first gate and the second gate are integrally formed as a columnar structure, the first semiconductor layer and the second semiconductor layer are integrally formed as a cylindrical structure, the cylindrical structure is arranged around the columnar structure, and the first source, the common electrode, and the second drain are arranged at intervals in the direction perpendicular to the base substrate and are arranged around the cylindrical structures.

In some embodiments, the capacitor is disposed on one side, away from the base substrate, of the second drain, and a first electrode of the capacitor is connected to the second drain.

According to some embodiments of the present disclosure, a method for manufacturing a memory is provided, including:
forming, by a patterning process, a plurality of repeating units spaced apart from each other on one side of a base substrate, wherein each of the repeating units includes a first source, a first semiconductor layer, a common electrode, a second semiconductor layer, and a second drain which are stacked;
forming a first gate and a second gate on outer sidewalls of the first semiconductor layer and the second semiconductor layer respectively;
forming a bit line connected to the first source;
forming a word line connected to the first gate and the second gate; and
forming a capacitor electrically connected to the drain on one side, away from the base substrate, of the second drain.

In some embodiments, forming, by the patterning process, the plurality of repeating units spaced apart from each other on one side of the base substrate includes: forming, by the patterning process, a plurality of initial repeating units spaced apart from each other on one side of the base substrate, wherein the initial repeating unit includes the first source, a first initial semiconductor layer, the common electrode, a second initial semiconductor layer, and the second drain which are stacked; and forming the repeating units by laterally etching the first initial semiconductor layers and the second initial semiconductor layers of the initial repeating units.

In some embodiments, forming the word line connected to the first gate and the second gate includes: forming an initial word line layer filled between all the repeating units; and forming the word line extending in a second direction parallel to the base substrate by patterning the initial word line layer.

### BRIEF DESCRIPTION OF THE DRAWINGS

The above and/or additional aspects and advantages of the present disclosure will become apparent and readily understood from the following description of embodiments in conjunction with the accompanying drawings, in which:

FIG. 1 is a schematic structural diagram of a circuit principle of a memory cell in a memory according to some embodiments of the present disclosure;

FIG. 2 is a schematic structural diagram of a memory cell in a memory according to some embodiments of the present disclosure;

FIG. 3 is a schematic structural top view of another memory according to some embodiments of the present disclosure;

FIG. 4 is a schematic cross-sectional structural diagram of the memory shown in FIG. 3 along an AA direction according to some embodiments of the present disclosure;

FIG. 5 is a schematic cross-sectional structural diagram of the memory shown in FIG. 3 along a BB direction according to some embodiments of the present disclosure;

FIG. 6 is a schematic structural diagram of a memory cell in still another memory according to some embodiments of the present disclosure;

FIG. 7 is a flowchart of a method for manufacturing a memory according to some embodiments of the present disclosure;

FIG. 8a is a schematic structural top view illustrating a first dopant layer is prepared by the method for manufacturing the memory according to some embodiments of the present disclosure;

FIG. 8b is a schematic cross-sectional structural diagram of the structure shown in FIG. 8a along an AA direction according to some embodiments of the present disclosure;

FIG. 8c is a schematic cross-sectional structural diagram of the structure shown in FIG. 8a along a BB direction according to some embodiments of the present disclosure;

FIG. 9a is a schematic structural top view illustrating a first intermediate substrate prepared by the method for manufacturing the memory according to some embodiments of the present disclosure;

FIG. 9b is a schematic cross-sectional structural diagram of the first intermediate substrate shown in FIG. 9a along an AA direction according to some embodiments of the present disclosure;

FIG. 9c is a schematic cross-sectional structural diagram of the first intermediate substrate shown in FIG. 9a along a BB direction according to some embodiments of the present disclosure;

FIG. 10a is a schematic structural top view illustrating a first mask structure prepared by the method for manufacturing the memory according to some embodiments of the present disclosure;

FIG. 10b is a schematic cross-sectional structural diagram of the structure shown in FIG. 10a along an AA direction according to some embodiments of the present disclosure;

FIG. 10c is a schematic cross-sectional structural diagram of the structure shown in FIG. 10a along a BB direction according to some embodiments of the present disclosure;

FIG. 11a is a schematic structural top view illustrating a second trench and an intermediate repeating unit prepared by the method for manufacturing the memory according to some embodiments of the present disclosure;

FIG. 11b is a schematic cross-sectional structural diagram of the structure shown in FIG. 11a along an AA direction according to some embodiments of the present disclosure;

FIG. 11c is a schematic cross-sectional structural diagram of the structure shown in FIG. 11a along a BB direction according to some embodiments of the present disclosure;

FIG. 12a is a schematic structural top view illustrating a second mask structure prepared by the method for manufacturing the memory according to some embodiments of the present disclosure;

FIG. 12b is a schematic cross-sectional structural diagram of the structure shown in FIG. 12a along an AA direction according to some embodiments of the present disclosure;

FIG. 12c is a schematic cross-sectional structural diagram of the structure shown in FIG. 12a along a BB direction according to some embodiments of the present disclosure;

FIG. 13a is a schematic structural top view illustrating an initial repeating unit prepared by the method for manufacturing the memory according to some embodiments of the present disclosure;

FIG. 13b is a schematic cross-sectional structural diagram of the structure shown in FIG. 13a along an AA direction according to some embodiments of the present disclosure;

FIG. 13c is a schematic cross-sectional structural diagram of the structure shown in FIG. 13a along a BB direction according to some embodiments of the present disclosure;

FIG. 14a is a schematic structural top view illustrating a first semiconductor layer and a second semiconductor layer prepared by the method for manufacturing the memory according to some embodiments of the present disclosure;

FIG. 14b is a schematic cross-sectional structural diagram of the structure shown in FIG. 14a along an AA direction according to some embodiments of the present disclosure;

FIG. 14c is a schematic cross-sectional structural diagram of the structure shown in FIG. 14a along a BB direction according to some embodiments of the present disclosure;

FIG. 15a is a schematic structural top view illustrating a first gate and a second gate prepared by the method for manufacturing the memory according to some embodiments of the present disclosure;

FIG. 15b is a schematic cross-sectional structural diagram of the structure shown in FIG. 15a along an AA direction according to some embodiments of the present disclosure;

FIG. 15c is a schematic cross-sectional structural diagram of the structure shown in FIG. 15a along a BB direction according to some embodiments of the present disclosure;

FIG. 16a is a schematic structural top view illustrating a bit line prepared by the method for manufacturing the memory according to some embodiments of the present disclosure;

FIG. 16b is a schematic cross-sectional structural diagram of the structure shown in FIG. 16a along a BB direction according to some embodiments of the present disclosure;

FIG. 17a is a schematic structural top view illustrating a third insulating layer prepared by the method for manufacturing the memory according to some embodiments of the present disclosure;

FIG. 17b is a schematic cross-sectional structural diagram of the structure shown in FIG. 17a along an AA direction according to some embodiments of the present disclosure;

FIG. 17c is a schematic cross-sectional structural diagram of the structure shown in FIG. 17a along a BB direction according to some embodiments of the present disclosure;

FIG. 18a is a schematic structural top view illustrating an initial word line prepared by the method for manufacturing the memory according to some embodiments of the present disclosure;

FIG. 18b is a schematic cross-sectional structural diagram of the structure shown in FIG. 18a along an AA direction according to some embodiments of the present disclosure;

FIG. 18c is a schematic cross-sectional structural diagram of the structure shown in FIG. 18a along a BB direction according to some embodiments of the present disclosure;

FIG. 19a is a schematic structural top view illustrating a third mask structure prepared by the method for manufacturing the memory according to some embodiments of the present disclosure;

FIG. 19b is a schematic cross-sectional structural diagram of the structure shown in FIG. 19a along an AA direction according to some embodiments of the present disclosure;

FIG. 19c is a schematic cross-sectional structural diagram of the structure shown in FIG. 19a along a BB direction according to some embodiments of the present disclosure;

FIG. 20a is a schematic structural top view illustrating a word line prepared by the method for manufacturing the memory according to some embodiments of the present disclosure;

FIG. 20b is a schematic cross-sectional structural diagram of the structure shown in FIG. 20a along an AA direction according to some embodiments of the present disclosure;

FIG. 20c is a schematic cross-sectional structural diagram of the structure shown in FIG. 20a along a BB direction according to some embodiments of the present disclosure;

FIG. 21a is a schematic structural top view illustrating a first sub-dielectric layer prepared by the method for manufacturing the memory according to some embodiments of the present disclosure;

FIG. 21b is a schematic cross-sectional structural diagram of the structure shown in FIG. 21a along an AA direction according to some embodiments of the present disclosure;

FIG. 21c is a schematic cross-sectional structural diagram of the structure shown in FIG. 21a along a BB direction according to some embodiments of the present disclosure;

FIG. 22a is a schematic structural top view illustrating a second intermediate substrate prepared by the method for manufacturing the memory according to some embodiments of the present disclosure;

FIG. 22b is a schematic cross-sectional structural diagram of the second intermediate substrate shown in FIG. 22a along an AA direction according to some embodiments of the present disclosure; and

FIG. 22c is a schematic cross-sectional structural diagram of the second intermediate substrate shown in FIG. 22a along a BB direction according to some embodiments of the present disclosure.

### DETAILED DESCRIPTION

Embodiments of the present disclosure are described below in conjunction with the accompanying drawings in the present disclosure. It should be understood that the embodiments set forth below in conjunction with the accompanying drawings are exemplary descriptions for explaining technical solutions of the embodiments of the present disclosure, and do not limit the technical solutions of the embodiments of the present disclosure.

It should be understood by those skilled in the art that the singular forms “a”, “an”, “one”, and “the” used herein are intended to include plural forms as well, unless specifically stated. It should be further understood that the term “include” used in the description of the present disclosure refers to the presence of the features, integers, steps, and/or operations, but does not exclude the implementation of other features, information, data, steps, operations, and/or their combinations supported in this art. The term “and/or” used herein refers to at least one of the items limited by the term. For example, “A and/or B” can be implemented as “A”, “B”, or “A and B”.

In order to describe the objects, technical solutions, and advantages of the present disclosure more clearly, the following briefly describes embodiments of the present disclosure in detail with reference to the accompanying drawings.

Several nouns involved in the present disclosure are to be described and explained first.

### DRAM: Dynamic Random Access Memory; and

Leakage current: referring to a dark current of a transistor in the DRAM that passes through a channel in an off state. The dark current will increase exponentially as the size of the transistor decreases and the channel shortens.

At present, a memory cell in the DRAM typically includes a transistor and a capacitor. As the size of the memory cell decreases, a leakage current of a transistor in the memory cell increases significantly.

The present disclosure provides a memory and a method for manufacturing the same, which aims to solve the technical problems in the prior art.

The technical solutions of the present disclosure are to be described in detail below with reference to specific embodiments.

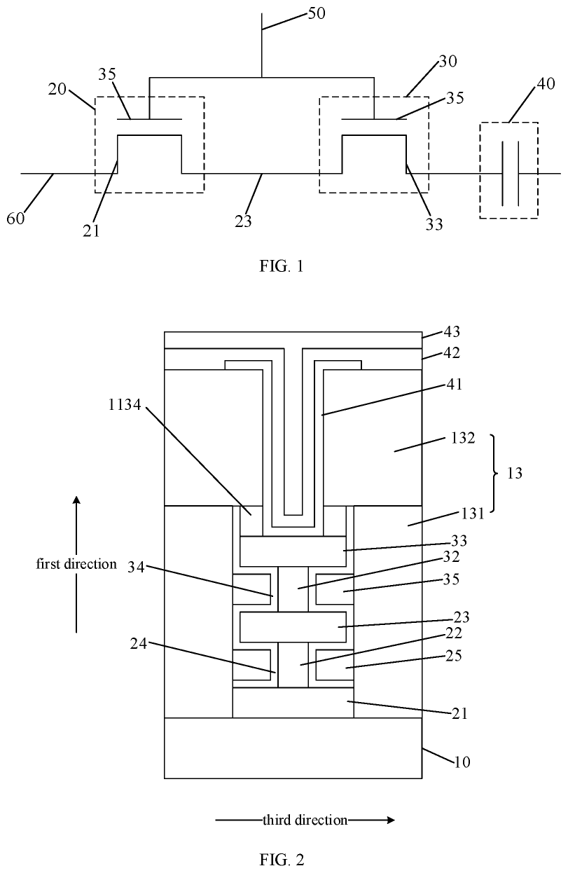

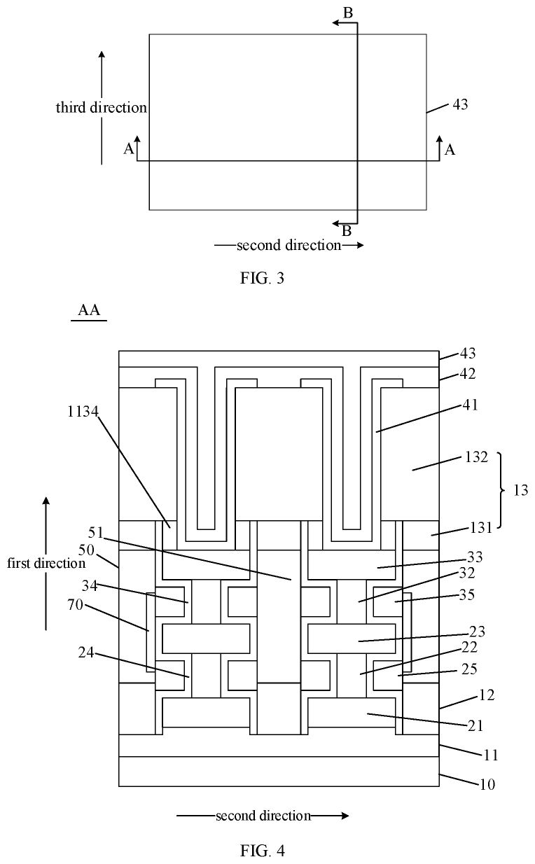

Embodiments of the present disclosure provide a memory. The memory includes a plurality of memory cells, a plurality of word lines, and a plurality of bit lines. A schematic structural diagram of a circuit principle of a memory cell in the memory is as shown in FIG. 1.

In some embodiments of the present disclosure, the memory cell includes: a first transistor 20, wherein a first source 21 of the first transistor 20 is electrically connected to a bit line 60; a second transistor 30, connected to the first transistor 20 in series; a capacitor 40, electrically connected to a second drain 33 of the second transistor 30, wherein the first transistor 20 and the second transistor 30 are n-type transistors or p-type transistors, and a first gate 25 of the first transistor 20 and a second gate 35 of the second transistor 30 are electrically connected to a word line 50.

In the memory provided in the embodiments of the present disclosure, the memory cell includes the first transistor 20 and the second transistor 30 connected to the first transistor in series. Compared with a memory cell only has one transistor, the memory of the present disclosure has the advantages that a voltage difference applied to one transistor is shared by the first transistor 20 and the second transistor 30 connected in series to the first transistor, such that a drain voltage of the first transistor 20 can be significantly reduced, and a leakage current in the memory cell of the present disclosure can be reduced, thus ensuring the working performance of the memory of the present disclosure.

It is understood by those skilled in the art that for a transistor, the leakage current of the transistor is mainly caused by an interband tunneling effect of a P-N junction near a drain. After testing, the inventor of the present disclosure has found that under the condition that the size of the transistor is fixed, the leakage current increases exponentially as a drain voltage increases.

In some embodiments of the present disclosure, as shown in FIG. 1, the memory cell includes the first transistor 20 and the second transistor 30 connected in series to the first transistor. Because the first transistor 20 is connected to the second transistor 30 in series, compared with a memory cell only has one transistor, the memory of the present disclosure has the advantages that a voltage difference applied to one transistor is shared by the first transistor 20 and the second transistor 30 connected to the first transistor in series, such that a drain voltage of the first transistor 20 can be significantly reduced, and a leakage current decreases exponentially as the drain voltage decreases. Therefore, the leakage current in the memory cell of the present disclosure can be reduced, and the working performance of the memory cell can be ensured.

It should be understood by those skilled in the art that a current of the transistor mainly depends on a voltage applied to a gate. In some embodiments of the present disclosure, the first gate 25 of the first transistor 20 and the second gate 35 of the second transistor 30 are electrically connected to the word line 50, such that values of currents flowing through the first transistor 20 and the second transistor 30 are the same. A voltage shared by the first transistor 20 can be further reduced by controlling a gate voltage of the second transistor 30, such that the drain voltage of the first transistor 20 can be further reduced. Therefore, the leakage current in the memory cell of the present disclosure can be reduced, and the working performance of the memory cell can be ensured.

In some embodiments of the present disclosure, as shown in FIG. 1, the first source 21 of the first transistor 20 is electrically connected to the bit line 60, and the capacitor 40 is electrically connected to the second drain 33 of the second transistor 30.

In some embodiments of the present disclosure, the first transistor 20 and the second transistor 30 are n-type transistors or p-type transistors.

As shown in FIG. 2, in some embodiments of the present disclosure, the first transistor 20 and the second transistor 30 are vertical transistors, and the first transistor 20 and the second transistor 30 are stacked in a direction perpendicular to a base substrate 10.

In some embodiments of the present disclosure, the first transistor 20 and the second transistor 30 are vertical transistors. In some embodiments, the vertical transistor refers to a transistor having a vertical structure, indicating a vertical gate-all-around (VGAA) transistor. Therefore, an area occupied by the memory cell on the base substrate 10 in a first direction can be decreased, and the storage density of the memory can be increased.

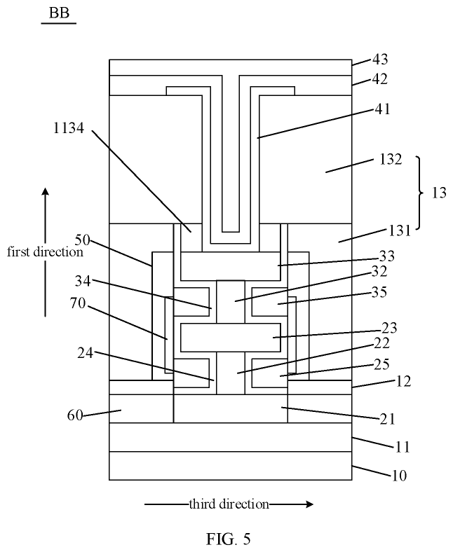

In some embodiments of the present disclosure, as shown in FIG. 2, FIG. 4 and FIG. 5, the first transistor 20 and the second transistor 30 are stacked sequentially on one side of the base substrate 10 in the first direction perpendicular to the base substrate 10. Specifically, the first transistor 20 is disposed on one side of the base substrate 10, and the second transistor 30 is disposed on one side, away from the base substrate 10, of the first transistor 20.

In some embodiments, the first transistor 20, the second transistor 30, and the capacitor 40 are stacked sequentially on one side of the base substrate 10, and the first transistor 20, the second transistor 30, and the capacitor 40 are connected to each other in series.

As shown in FIG. 2, in some embodiments of the present disclosure, a common electrode 23 is disposed between the first transistor 20 and the second transistor 30 in the direction perpendicular to the base substrate. The first transistor 20 is connected to the second transistor 30 in series through the common electrode 23, and a first drain of the first transistor 20 and a second source of the second transistor 30 constitute the common electrode 23.

It should be noted that in some embodiments of the present disclosure, the common electrode 23 is the first drain of the first transistor 20 and the second source of the second transistor 30.

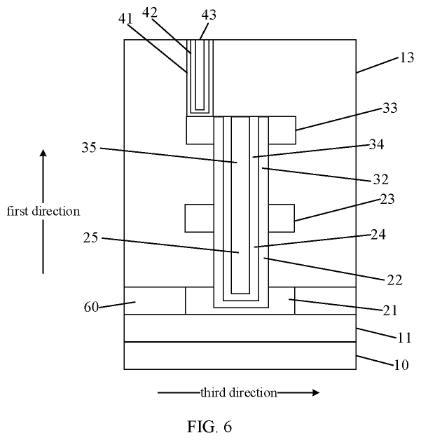

In some embodiments of the present disclosure, as shown in FIG. 2, FIG. 4, FIG. 5, and FIG. 6, the first transistor 20 is connected to the second transistor 30 in series through the common electrode 23, and the common electrode 23 is formed by the first drain of the first transistor 20 and the second source of the second transistor 30, such that a volume occupied by the first transistor 20 and the second transistor 30 can be reduced, and the storage density of the cell of the memory can be ensured.

As shown in FIG. 2 and FIGS. 4 to 6, in some embodiments of the present disclosure, the first transistor 20 includes a first semiconductor layer 22, the second transistor 30 includes a second semiconductor layer 32, and the first semiconductor layer 22 and the second semiconductor layer 32 are stacked in the direction perpendicular to the base substrate 10.

In some embodiments of the present disclosure, as shown in FIG. 2 and FIGS. 4 to 6, the first semiconductor layer 22 of the first transistor 20 and the second semiconductor layer 32 of the second transistor 30 are stacked in the first direction.

In some embodiments, as shown in FIG. 2, FIG. 4 and FIG. 5, the first semiconductor layer 22 and the second semiconductor layer 32 are spaced apart from each other and stacked on one side of the base substrate 10 in the first direction.

In some embodiments, as shown in FIG. 6, the first semiconductor layer 22 and the second semiconductor layer 32 are stacked sequentially on one side of the base substrate 10 in the first direction.

In some embodiments of the present disclosure, the common electrode 23 includes two sub-electrodes stacked with each other. The lower sub-electrode serves as the first drain of the first transistor 20, and the upper sub-electrode serves as the second source of the second transistor 30. In some embodiments, the common electrode 23 is only a single-layer electrode, which serves as both the first drain of the first transistor 20 and the second source of the second transistor 30.

In the case that the common electrode 23 is the single-layer electrode, the first transistor 20 and the second transistor 30 share one common electrode 23, such that a thickness occupied by the first transistor 20 and the second transistor 30 can be reduced, which is conducive to increasing a vertical stacking density of the memory cell. Moreover, the structures of the first transistor 20 and the second transistor 30 can be simplified, and the manufacturing process can be simplified.

As shown in FIG. 2, FIG. 4 and FIG. 5, in some embodiments of the present disclosure, the common electrode 23 is arranged between the first semiconductor layer 22 and the second semiconductor layer 32 in the direction perpendicular to the base substrate 10, the first gate 25 and the first semiconductor layer 22 are arranged on the same layer, and the second gate 35 and the second semiconductor layer 32 are arranged on the same layer.

In some embodiments of the present disclosure, as shown in FIG. 2, FIG. 4 and FIG. 5, the first semiconductor layer 22, the common electrode 23, and the second semiconductor layer 32 are stacked sequentially on one side of the base substrate 10 in the first direction. The first semiconductor layer 22 and the second semiconductor layer 32 are connected to the common electrode 23. In some embodiments, the first semiconductor layer 22 is connected to one side surface of the common electrode 23 close to the first source 21, and the second semiconductor layer 32 is connected to the other side surface, away from the first source 21, of the common electrode 23.

In some embodiments, as shown in FIG. 2, FIG. 4 and FIG. 5, the first gate 25 and the second gate 35 are stacked in the first direction.

As shown in FIG. 2, FIG. 4 and FIG. 5, the first gate 25 and the first semiconductor layer 22 are arranged on the same layer. In some embodiments, the first gate 25 and the first semiconductor layer 22 are disposed between the first source 21 and the common electrode 23.

As shown in FIG. 2, FIG. 4 and FIG. 5, the second gate 35 and the second semiconductor layer 32 are arranged on the same layer. In some embodiments, the second gate 35 and the second semiconductor layer 32 are disposed between the common electrode 23 and the second drain 33.

As shown in FIG. 2, FIG. 4 and FIG. 5, in some embodiments of the present disclosure, the first gate 25 is arranged around the first semiconductor layer 22 and is insulated from the first semiconductor layer 22, and the second gate 35 is arranged around the second semiconductor layer 32 and is insulated from the second semiconductor layer 32.

In some embodiments, as shown in FIG. 2, FIG. 4 and FIG. 5, the first gate 25 is arranged around an outer sidewall of the first semiconductor layer 22. A first insulating structure 24 is arranged between the first gate 25 and the first semiconductor layer 22 in a second direction parallel to the base substrate 10 and a third direction parallel to the base substrate 10, such that the first gate 25 is insulated from the first semiconductor layer 22. That is, the first insulating structure 24 is arranged around the first semiconductor layer 22, and the first gate 25 is arranged around the first insulating structure 24. In some embodiments, the second direction is perpendicular to the third direction.

As shown in FIG. 2, FIG. 4 and FIG. 5, the second gate 35 is arranged around an outer sidewall of the second semiconductor layer 32. A second insulating structure 34 is arranged between the second gate 35 and the second semiconductor layer 32 in the second direction parallel to the base substrate 10 and the third direction parallel to the base substrate 10, such that the second gate 35 is insulated from the second semiconductor layer 32. That is, the second insulating structure 34 is arranged around the second semiconductor layer 32, and the second gate 35 is arranged around the second insulating structure 34.

As shown in FIG. 2, FIG. 4 and FIG. 5, in some embodiments of the present disclosure, each of the first semiconductor layer 22, the common electrode 23, and the second semiconductor layer 32 is in a columnar structure, the first source 21 is arranged at one end, away from the common electrode 23, of the first semiconductor layer 22 or on a circumferential wall of a portion of the first semiconductor layer 22, and the second drain 33 is arranged at one end, away from the common electrode 23, of the second semiconductor layer 32 or on a circumferential wall of a portion of the second semiconductor layer 32.

In some embodiments, as shown in FIG. 2, FIG. 4 and FIG. 5, each of the first semiconductor layer 22, the second semiconductor layer 32, and the common electrode 23 is in a columnar structure. In some embodiments, the columnar structure is a circular column, a square column, a rectangular column, a rounded square column, or the like.

In some embodiments, as shown in FIG. 2, FIG. 4 and FIG. 5, the first source 21 is arranged at one end, away from the common electrode 23, of the first semiconductor layer 22, and the second drain 33 is arranged at one end, away from the common electrode 23, of the second semiconductor layer 32, such that the first source 21, the first semiconductor layer 22, the common electrode 23, the second semiconductor layer 32, and the second drain 33 are stacked sequentially on one side of the base substrate 10 in the first direction.

In some embodiments, the first source 21 is arranged on the circumferential wall of the portion of the first semiconductor layer 22, such that a height of the memory cell in the first direction is reduced. In some embodiments, the second drain 33 is arranged on the circumferential wall of the portion of the second semiconductor layer 32, such that the height of the memory cell in the first direction is further reduced.

As shown in FIG. 2, FIG. 4 and FIG. 5, in some embodiments of the present disclosure, orthographic projections of the first semiconductor layer 22 and the second semiconductor layer 32 on the base substrate 10 are within orthographic projections of the first source 21, the common electrode 23, and the second drain 33 on the base substrate 10; and orthographic projections of at least a portion of the first gate 25 and at least a portion of the second gate 35 on the base substrate 10 are within the orthographic projections of the first source 21, the common electrode 23, and the second drain 33 on the base substrate 10.

In some embodiments of the present disclosure, as shown in FIG. 2, FIG. 4 and FIG. 5, each of the orthographic projections of the first source 21, the common electrode 23, and the second drain 33 on the base substrate 10 covers the orthographic projection of the first semiconductor layer 22 on the base substrate 10. That is, the first source 21 and the common electrode 23 protrude outwards relative to the first semiconductor layer 22, such that outer sidewalls of the first source 21, the common electrode 23, and the first semiconductor layer 22 form a lateral groove. In some embodiments, the groove is an annular groove.

As shown in FIG. 2, FIG. 4 and FIG. 5, each of the orthographic projections of the first source 21, the common electrode 23, and the second drain 33 on the base substrate 10 covers the orthographic projection of the second semiconductor layer 32 on the base substrate 10. That is, the common electrode 23 and the second drain 33 protrude outwards relative to the second semiconductor layer 32, such that outer sidewalls of the common electrode 23, the second drain 33, and the first semiconductor layer 22 form a lateral groove. In some embodiments, the groove is also an annular groove.

In some embodiments, the orthographic projections of the first source 21, the common electrode 23, and the second drain 33 on the base substrate 10 are overlapped with each other, such that the consistency in the sizes of the first transistor 20 and the second transistor 30 is guaranteed, and the consistency in the working performances of the first transistor 20 and the second transistor 30 is guaranteed.

In some embodiments, as shown in FIG. 2, FIG. 4 and FIG. 5, orthographic projections of at least a portion of the first gate 25 and at least a portion of the second gate 35 on the substrate 10 are within the orthographic projections of the first source 21, the common electrode 23, and the second drain 33 on the base substrate 10, such that an electric field of the first gate 25 affects the first semiconductor layer 22, and an electric field of the second gate 35 affects the second semiconductor layer 32.

In some embodiments, as shown in FIG. 2, FIG. 4 and FIG. 5, the first gate 25 protrudes outwards relative to the first source 21 and the common electrode 23, and the second gate 35 protrudes outwards relative to the common electrode 23 and the second drain 33, so as to facilitate the connection of the first gate 25 and the second gate 35 to the word line 50.

In some embodiments, as shown in FIG. 2, FIG. 4, and FIG. 5, in the first transistor 20, the first gate 25 is disposed on the outer sidewall of the first semiconductor layer 22. In some embodiments, the first semiconductor layer 22 is recessed relative to the first source 21 and the common electrode 23 in the third direction, such that a first lateral groove is formed, and the first insulating structure 24 and the first gate 25 are disposed in the first lateral groove.

In some embodiments, as shown in FIG. 2, FIG. 4, and FIG. 5, in the second transistor 30, the second gate 35 is disposed on the outer sidewall of the second semiconductor layer 32. In some embodiments, the second semiconductor layer 32 is recessed relative to the common electrode 23 and the second drain 33 in the third direction, such that a second lateral groove is formed, and the second insulating structure 34 and the second gate 35 are disposed in the second lateral groove.

As shown in FIG. 4 and FIG. 5, in some embodiments of the present disclosure, the memory cell further includes a connection electrode 70, arranged around outer sidewalls of the first gate 25 and the second gate 35, and the first gate 25 and the second gate 35 are connected to the connection electrode 70.

In some embodiments, as shown in FIG. 4 and FIG. 5, the connection electrode 70 is arranged around outer sidewalls of a portion of the first gate 25, the common electrode 23, and a portion of the second gate 35, such that the first gate 25 and the second gate 35 are connected to the connection electrode 70.

In some embodiments, the connection electrode 70, the first gate 25, and the second gate 35 are made of the same material, which facilitates forming the connection electrode, the first gate, and the second gate simultaneously.

As shown in FIG. 4, in some embodiments of the present disclosure, the word line 50 includes a plurality of subsections 51 sequentially connected to each other, each of the subsections 51 is arranged around outer sidewalls of the first gate 25, the common electrode 23, the second gate 35, and the second drain 33, and a surface of the subsection 51 is flush with a surface, away from the common electrode 23, of the second drain 33.

In some embodiments, as shown in FIG. 4, the first transistor 20 and the second transistor 30 form a stacked structure. The subsections 51 of the word line 50 is arranged between two adjacent stacked structures. The subsections 51 surround the outer sidewalls of the first gate 25, the common electrode 23, the second gate 35, and the second drain 33. Upper surfaces of the subsections 51 are flush with an upper surface of the second drain 33 of the second transistor 30 in the first direction, such that the probability of contact connection between the subsections 51 and the capacitor 40 is reduced.

In some embodiments of the present disclosure, the size of the first semiconductor layer 22 is equal to the size of the second semiconductor layer 32 in the first direction. That is, the thickness of the first semiconductor layer 22 is equal to the thickness of the second semiconductor layer 32, such that the leakage current in the memory cell of the present disclosure can be reduced, and the manufacturing difficulty can be reduced. In this way, the consistency in the sizes of the first transistor 20 and the second transistor 30 is ensured and the consistency in the working performances of the first transistor 20 and the second transistor 30 is ensured.

As for a memory cell only has one transistor, it is assumed that a thickness of a semiconductor layer in the transistor is 2 L. In some embodiments of the present disclosure, the first transistor 20 having the first semiconductor layer 22 with a thickness of L and the second transistor 30 having the second semiconductor layer 32 with a thickness of L are connected to each other in series. Because the current in each transistor mainly depends on the gate voltage and drain voltage of the transistor, in the case that the gate voltages, the thicknesses of the first semiconductor layer 22 and the second semiconductor layer 32 are the same, the drain voltage of the first transistor 20 is significantly reduced. As the leakage current decreases exponentially as the drain voltage decreases, the leakage current in the memory cell of the present disclosure is reduced, and the working performance of the memory cell is ensured.

It should be noted that in some embodiments of the present disclosure, the function of the first source 21 of the first transistor 20 and the common electrode 23 are interchangeable. That is, the first source 21 serves as one of the source and the drain, and the common electrode 23 serves as the other one of the source and the drain. The second transistor 30 is similar, which is not repeated herein.

In some embodiments of the present disclosure, the plurality of memory cells are arranged in an array. The bit lines 60 are arranged on one side of the base substrate 10 and are parallel to the third direction. The memory cells disposed in one row in the third direction are connected to the one bit line 60. The word lines 50 are parallel to the second direction. The memory cells disposed in one column in the second direction are connected to one word line 50. The second direction and the third direction are parallel to the base substrate 10.

In some embodiments of the present disclosure, the memory cells arranged in the array are disposed on one sides, away from the base substrate 10, of the bit lines 60, and the bit lines 60 are connected to the first sources 21 of the first transistors 20 arranged in the third direction. In some embodiments, the bit line 60 and the first source 21 are prepared from the same conductive layer. A specific preparation process flow is to be described in detail in a following method for manufacturing the memory, which is not repeated herein.

In some embodiments of the present disclosure, the word line 50 extends in a direction parallel to the base substrate 10 and is connected to the first gate 25 and the second gate 35.

In some embodiments of the present disclosure, as shown in FIG. 2, FIG. 4, FIG. 5, and FIG. 6, the word line 50 extends in the second direction parallel to the base substrate 10 and is connected to the first gate 25 and the second gate 35, such that the first transistor 20 and the second transistor 30 connected in series to the first transistor are simultaneously driven by the same word line 50.

As shown in FIG. 6, in some embodiments of the present disclosure, the first semiconductor layer 22 is arranged around an outer sidewall of the first gate 25 and is insulated from the first gate 25, and the second semiconductor layer 32 is arranged around an outer sidewall of the second gate 35 and is insulated from the second gate 35.

In some embodiments, the first transistor 20 and the second transistor 30 are vertical transistors. In some embodiments, a vertical transistor refers to a transistor having a vertical structure, indicating a channel all around gate (CAA) transistor.

As shown in FIG. 6, the first gate 25 and the second gate 35 are stacked in the first direction.

As shown in FIG. 6, in some embodiments of the present disclosure, the first gate 25 and the second gate 35 are integrally formed as a columnar structure, the first semiconductor layer 22 and the second semiconductor layer 32 are integrally formed as a cylindrical structure, the cylindrical structures are arranged around the columnar structures, and the first source 21, the common electrode 23, and the second drain 33 are arranged at intervals in the direction perpendicular to the base substrate 10 and are arranged around the cylindrical structures.

In some embodiments of the present disclosure, as shown in FIG. 6, the first gate 25 and the second gate 35 are integrally formed as a structure, and the first semiconductor layer 22 and the second semiconductor layer 32 are also integrally formed as a structure, such that the manufacturing of the second transistor 30 and the first transistor 20 is facilitated, and the manufacturing difficulty of the memory cell is lowered.

As shown in FIG. 2 and FIG. 4 to FIG. 6, in some embodiments of the present disclosure, the capacitor 40 is disposed on one side, away from the base substrate 10, of the second drain 33 of the second transistor 30, and a portion of a first electrode 41 of the capacitor 40 is connected to the second drain 33.

In some embodiments of the present disclosure, as shown in FIG. 2, FIG. 4, FIG. 5, and FIG. 6, the capacitor 40 is disposed on one side, away from the base substrate 10, of the second drain 33 of the second transistor 30. In some embodiments, at least a portion of the capacitor 40 is disposed in a first via hole of a first dielectric layer 13 on one side, away from the base substrate 10, of the second transistor 30. The capacitor 40 includes a first electrode 41, a second electrode 43, and a second dielectric layer 42 sandwiched between the first electrode 41 and the second electrode 43, and a portion of the first electrode 41 is connected to the second drain 33.

Based on the same inventive concept, the embodiments of the present disclosure provide an electronic device, including: a terminal device memory provided with the memory described above, such as a smart phone, a computer, a tablet, an artificial intelligence device, a wearable device, or a mobile power supply.

It should be noted that the electronic device is not limited to those described above, and those skilled in the art may provide, in various devices, any one of the memories as defined in the above embodiments of the present disclosure according to practical application needs, so as to acquire the electronic device provided by the embodiments of the present disclosure.

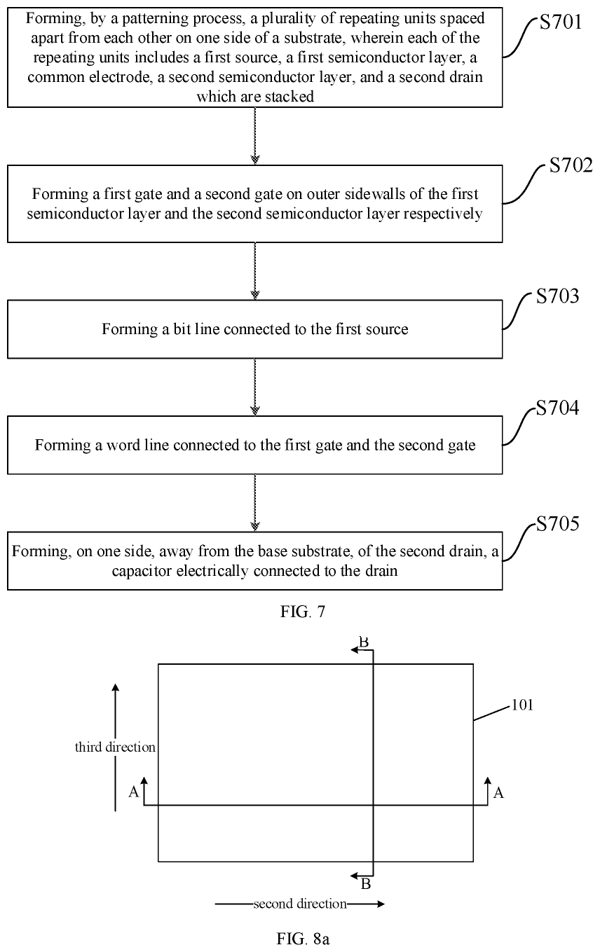

Based on the same inventive concept, the embodiments of the present disclosure provide a method for manufacturing a memory. The flowchart of the method is as shown in FIG. 7. The method includes the following steps S701-S705.

In S701, a plurality of repeating units spaced apart from each other are formed on one side of a base substrate by a patterning process, wherein each of the repeating units includes a first source, a first semiconductor layer, a common electrode, a second semiconductor layer, and a second drain which are stacked.

In S702, a first gate and a second gate are formed on outer sidewalls of the first semiconductor layer and the second semiconductor layer respectively.

In S703, a bit line connected to the first source is formed.

In S704, a word line connected to the first gate and the second gate is formed.

In S705, a capacitor electrically connected to the drain is formed on one side, away from the substrate, of the second drain.

In S702, an insulating layer is formed on outer sidewalls of the first source, the first semiconductor layer, the common electrode, the second semiconductor layer, and the second drain, and the first gate and the second gate are formed on an outer sidewall of the insulating layer.

In the method for manufacturing the memory according to the embodiments of the present disclosure, the first transistor 20 connected to the second transistor 30 in series is prepared. Compared with a memory cell provided with only one transistor, the memory of the present disclosure has the advantages that a voltage difference applied to one transistor is shared by the first transistor 20 and the second transistor 30 connected to the first transistor in series, such that a drain voltage of the first transistor 20 can be significantly reduced, and a leakage current in the memory cell of the present disclosure can be reduced, thus ensuring the working performance of the memory of the present disclosure.

Meanwhile, the prepared first transistor 20 and the prepared second transistor 30 share one common electrode 23, such that a volume occupied by the first transistor 20 and the second transistor 30 can be reduced, and the storage density of the cell of the memory can be ensured.

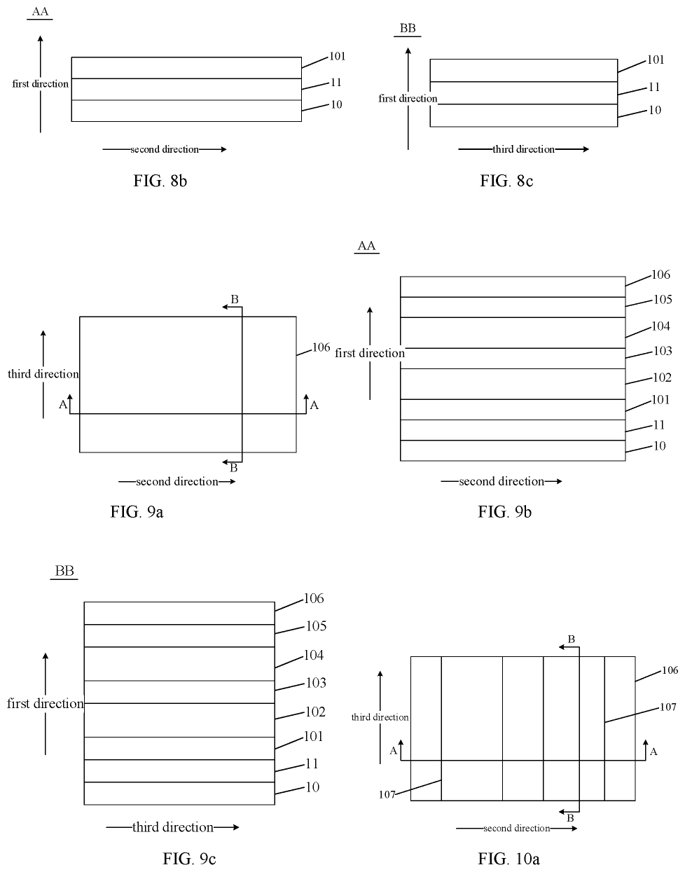

In order to facilitate readers to intuitively understand the advantages of the method for manufacturing the memory and the memory manufactured by the method provided by the embodiments of the present disclosure, the specific description is as follows with reference to FIGS. 8a to 22c.

In some embodiments of the present disclosure, in S701, forming the plurality of repeating units spaced apart from each other on one side of the substrate by the patterning process includes: forming a plurality of initial repeating units 113 spaced apart from each other on one side of the base substrate by the patterning process, wherein the initial repeating units 113 includes the first source 21, a first initial semiconductor layer 1132, the common electrode 23, a second initial semiconductor layer 1133, and the second drain 33 which are stacked, and forming the repeating units by laterally etching the first initial semiconductor layers 1132 and the second initial semiconductor layers 1133 of the initial repeating units 113. The step specifically includes the following steps.

First, a first isolation layer 11 is formed on one side of the base substrate 10, a dopant semiconductor layer is formed on one side of the first isolation layer 11 to acquire a first dopant layer 101, a first dopant semiconductor layer 102, a second dopant layer 103, a second dopant semiconductor layer 104, and a third dopant layer 105 are formed sequentially on one side of the first dopant layer 101 away from the base substrate 10 by adopting an epitaxial process, and a first intermediate substrate is acquired by forming a first protection layer 106 on one side, away from the base substrate 10, of the third dopant layer 105.

In some embodiments, the first isolation layer 11 is formed by performing deposition on one side of the base substrate 10 by a deposition process such as Chemical Vapor Deposition (CVD), Physical Vapor Deposition (PVD), or Atomic Layer Deposition (ALD). In some embodiments of the present disclosure, the base substrate 10 is subjected to P-type doping.

Then, the deposition process is used to form the dopant semiconductor layer on the side, away from the base substrate 10, of the first isolation layer 11, such that the semiconductor layer has good conductivity, and the first dopant layer 101 is acquired, as shown in FIGS. 8a to 8c. In some embodiments, the first doping layer 101 is heavily doped. The first dopant layer 101 is either subjected to N-type doping or subjected to P-type doping.

Then, the epitaxial process is used to form the first dopant semiconductor layer 102, the second dopant layer 103, the second dopant semiconductor layer 104, and the third dopant layer 105 sequentially on the side, away from the base substrate 10, of the first dopant layer 101. Next, the first intermediate substrate is acquired by forming the first protection layer 106 on the side, away from the base substrate 10, of the third dopant layer 105, as shown in FIGS. 9a to 9c.

In some embodiments, the second dopant layer 103 and the third dopant layer 105 are subjected to N-type doping. In some embodiments, the second dopant layer 103 and the third dopant layer 105 are subjected to in-situ doping.

In some embodiments of the present disclosure, forming materials of the first dopant semiconductor layer 102 and the second dopant semiconductor layer 104 include silicon germanium (SiGe), and a forming material of the first protection layer 106 includes silicon nitride. Because the silicon nitride has good etching resistance, the influence caused by a subsequent forming procedure on a film layer structure disposed below the first protection layer 106 is avoided.

Next, the first intermediate substrate is patterned to form at least two first trenches spaced apart from each other and parallel to a third direction and at least two initial repeating units spaced apart from each other and parallel to the third direction. This specifically includes the following steps.

First, at least two spaced first mask structures 107 are formed on the first intermediate substrate. The first mask structures 107 extend in the third direction.

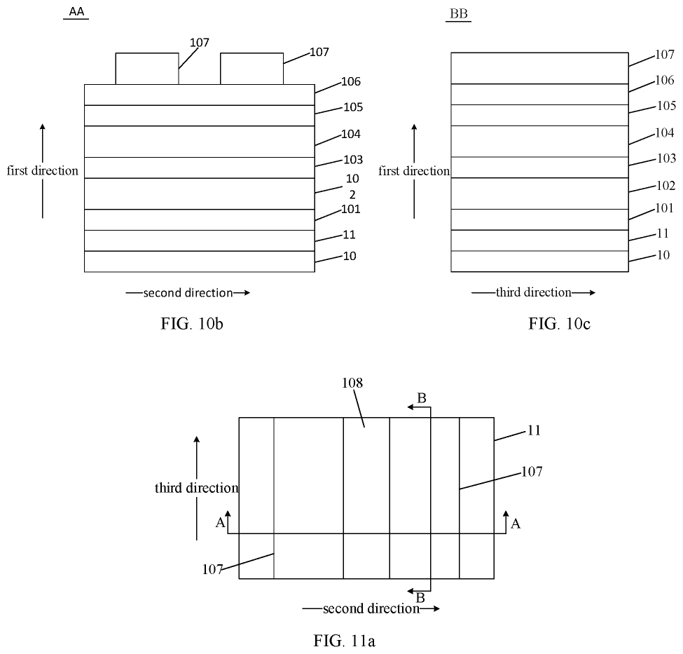

In some embodiments, one side, away from the base substrate 10, of the first protection layer 106 in the first intermediate substrate is coated with a photoresist layer, and at least two spaced first mask structures 107 are acquired by treating the photoresist layer through a process such as exposure and development, as shown in FIGS. 10a to 10c. The first mask structures 107 extend in the third direction.

Then, the first intermediate substrate is etched with the first mask structures 107 as masks, and the first mask structures 107 are removed to form at least two second trenches 108 spaced apart from each other and parallel to the third direction and at least two intermediate repeating units 109 spaced apart from each other and parallel to the third direction. The bottoms of the second trenches 108 penetrate through the first dopant layer 101.

In some embodiments, portions of the first intermediate substrate that are not covered by the first mask structures 107 are etched until a portion of the first isolation layer 11 is exposed, such that the spaced second trenches 108 and the spaced intermediate repeating units 109 are formed, as shown in FIGS. 11a to 11c. In some embodiments of the present disclosure, the bottoms of the second trenches 108 penetrate through the first dopant layer 101. In some embodiments, the bottoms of the second trenches 108 extend into a portion of the first isolation layer 11, so as to ensure that adjacent intermediate repeating units 109 are isolated from each other.

Next, a second insulating layer 110 is formed in the second trench 108, such that the second insulating layer 110 is flush with a surface of the intermediate repeating unit 109. A second mask structure 111 is formed on one side of the intermediate repeating unit 109, and an orthographic projection of the second mask structure 111 on the base substrate is within an orthographic projection of the intermediate repeating unit 109 on the base substrate 10.

In some embodiments, a silicon oxide layer is deposited and formed in the second trench 108 by the deposition process such as the PVD, the CVD, or the ALD. In the case that the silicon oxide layer is deposited and formed, the silicon oxide layer is treated by a Chemical Mechanical Polishing (CMP) process, such that the intermediate repeating unit 109 is exposed, and the second insulating layer 110 that is flush with the surface of the intermediate repeating unit 109 is acquired.

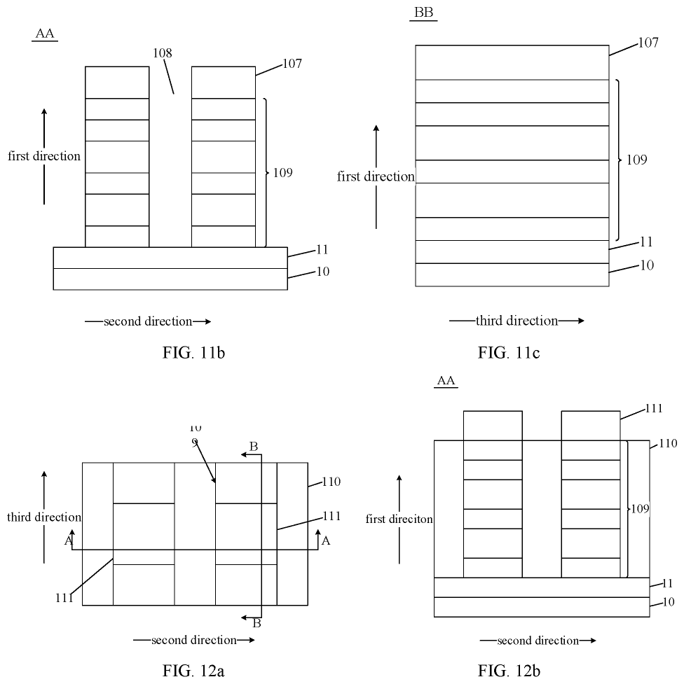

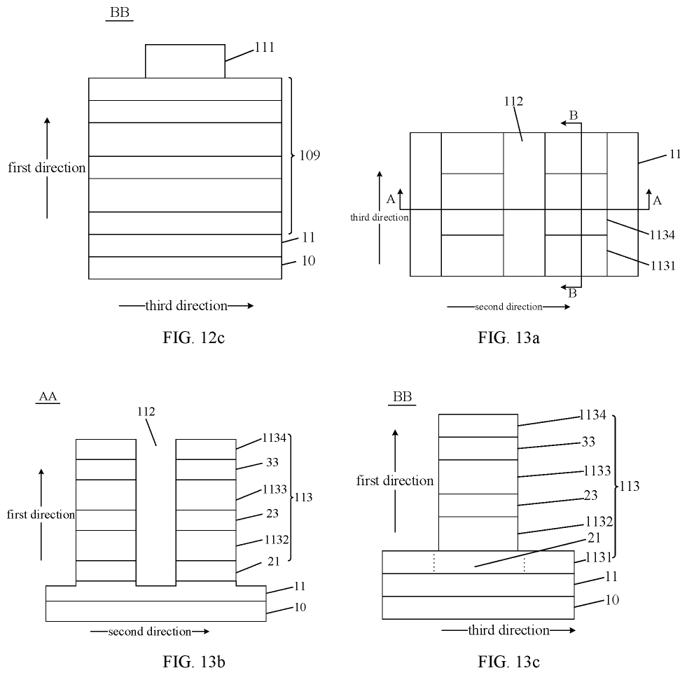

In some embodiments, one side, away from the base substrate 10, of the intermediate repeating unit 109 and one side, away from the base substrate 10, of the second insulating layer 110 are coated with photoresist layers, and at least two spaced second mask structures 111 are acquired by treating the photoresist layers through the process such as exposure and development, as shown in FIGS. 12a to 12c. An orthographic projection of the second mask structure 111 on the base substrate is within an orthographic projection of the intermediate repeating unit 109 on the base substrate 10. In some embodiments, two side edges of the second mask structure 111 in a second direction are flush with a side edge of the intermediate repeating unit 109.

Then, portions that are not covered by the second mask structures 111 are etched with the second mask structures 111 as masks, such that at least two first trenches 112 spaced apart from each other and parallel to the third direction are formed, and at least two initial repeating units 113 spaced apart from each other and parallel to the third direction are formed. The initial repeating unit 113 includes an initial bit line 1131, and the initial bit line 1131 includes the first source 21.

In some embodiments, portions not covered by the second mask structures 111 are etched until a portion of the first isolation layer 11 is exposed, such that the first trenches 112 spaced part from each other are formed, and the initial repeating units 113 spaced part from each other are formed, as shown in FIGS. 12a to 12c. In some embodiments of the present disclosure, bottoms of the first trenches 112 extend into a portion of the first isolation layer 11, so as to ensure that adjacent initial repeating units 113 are isolated from each other.

In some embodiments, as shown in FIGS. 13a to 13c, the initial repeating unit 113 includes the initial bit line 1131, the first initial semiconductor layer 1132, the common electrode 23, the second initial semiconductor layer 1133, the second drain 33, and a first protection structure 1134 which are stacked in a first direction. As shown in FIGS. 13a to 13c, the initial bit line 1131 extends in the third direction, and the initial bit line 1131 includes the first source 21. Specifically, in the third direction, a portion of the initial bit line 1131 overlapped with the common electrode 23 is the first source 21.

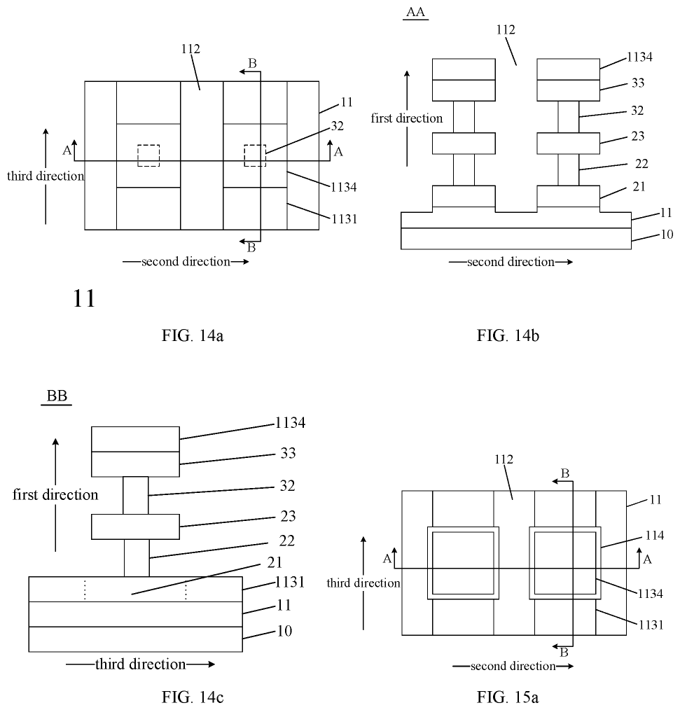

Next, forming the repeating units by laterally etching the first initial semiconductor layers 1132 and the second initial semiconductor layers 1133 of the initial repeating units 113 specifically includes: acquiring the first semiconductor layer 22 and the second semiconductor layer 32 by laterally etching the first initial semiconductor layers 1132 and the second initial semiconductor layers 1133 in all the initial repeating units 113, such that a circumferential surface of the first semiconductor layer 22 is recessed relative to the first source 21 and the common electrode 23 in a direction parallel to the base substrate 10, and a circumferential surface of the second semiconductor layer 32 is recessed relative to the common electrode 23 and the second drain 33 in the direction parallel to the base substrate 10. That is, the first source 21, the first semiconductor layer 22, and the common electrode 23 are enclosed to form a first lateral groove, and the common electrode 23, the second semiconductor layer 32, and the second drain 33 are enclosed to form a second lateral groove, as shown in FIGS. 14a to 14c.

In some embodiments of the present disclosure, as can be seen from FIGS. 14a to 14c, the first lateral groove is encircled in a circumferential direction of the first semiconductor layer 22, and the second lateral groove is encircled in a circumferential direction of the second semiconductor layer 32.

It should be noted that in FIG. 13c and FIG. 14c, a portion of the first source 21 in the initial bit line 1131 is shown by the dotted line, and the dotted line described above is not present in an actual product. The dotted lines in subsequent figures have the same meaning. The second semiconductor layer 32 which is covered is shown by the dotted line in FIG. 14a.

In some embodiments of the present disclosure, in S702, forming the first gate and the second gate on outer sidewalls of the first semiconductor layer 22 and the second semiconductor layer 23 respectively includes: forming a first insulating layer 114 on outer sidewalls of the first source 21, and forming the first semiconductor layer 22, the common electrode 23, the second semiconductor layer 32, and the second drain 33, and the first gate 25 and the second gate 35 on an outer sidewall of the first insulating layer 114. The step specifically includes the following steps.

First, a first insulating structure 24 disposed in the first lateral groove and a second insulating structure 34 disposed in the second lateral groove are acquired by forming the first insulating layer 114 conforming to circumferential surfaces on the circumferential surfaces of the first source 21, the first semiconductor layer 22, the common electrode 23, the second semiconductor layer 32, and the second drain 33 which are stacked.

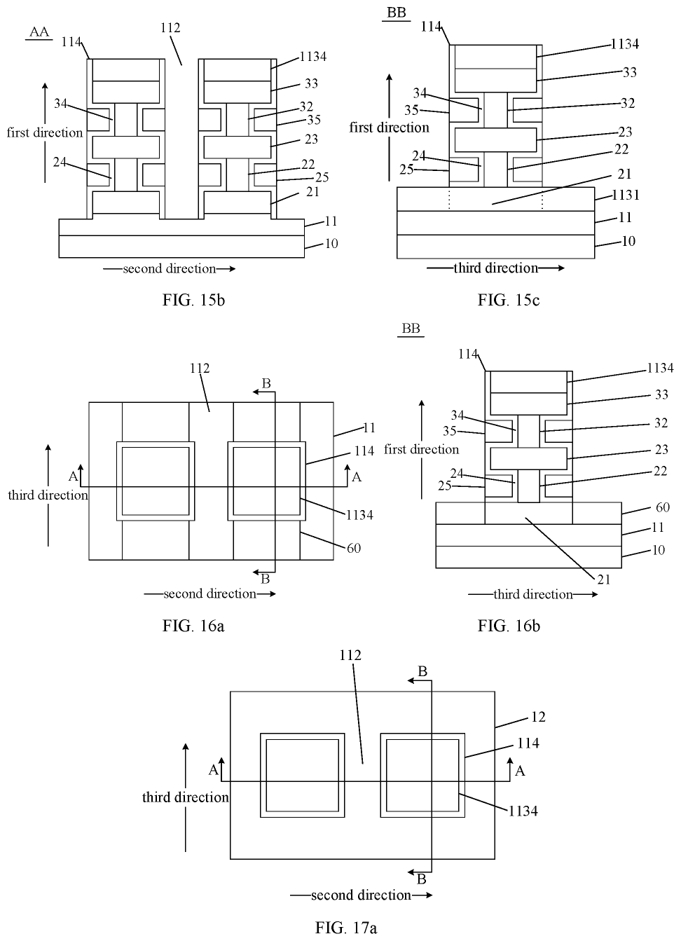

Then, a first transistor 20 and a second transistor 30 stacked with the first transistor in the first direction are acquired by depositing and forming the first gate 25 disposed in the first lateral groove and the second gate 35 disposed in the second lateral groove on a side surface of the first insulating layer 114, as shown in FIGS. 15a to 15c.

In some embodiments of the present disclosure, in S703, forming a bit line 60 connected to the first source 21 includes: acquiring the bit line 60 by treating a portion of the initial bit line 1131 other than the first source 21 by an annealing process.

In some embodiments, a titanium metal layer is formed on one side of a portion of the initial bit line 1131 other than the first source 21, and the portion of the initial bit line 1131 other than the first source 21 is treated by an annealing process, that is, a portion of the initial bit line 1131 not covered by the first insulating layer 114 is treated by the annealing process, such that the titanium metal layer reacts with a silicon material in the initial bit line 1131, and the metalized bit line 60 is acquired by removing a remaining unreacted portion of the titanium metal layer, as shown in FIG. 16a and FIG. 16b.

It should be noted that the schematic cross-sectional structural diagram along AA direction in FIG. 16a is the same as that in FIG. 15b, which is not illustrated.

In some embodiments of the present disclosure, in S704, forming a word line 50 connected to the first gate 25 and the second gate 35 includes: forming an initial word line layer 116 filled between all the repeating units, and forming the word line 50 extending in a direction parallel to the base substrate by patterning the initial word line layer 116. The step specifically includes the following steps.

First, a third insulating layer 12 is formed on one side of the base substrate 10, such that the third insulating layer 12 covers the bit line 60, and at least a portion of the first gate 25 is exposed.

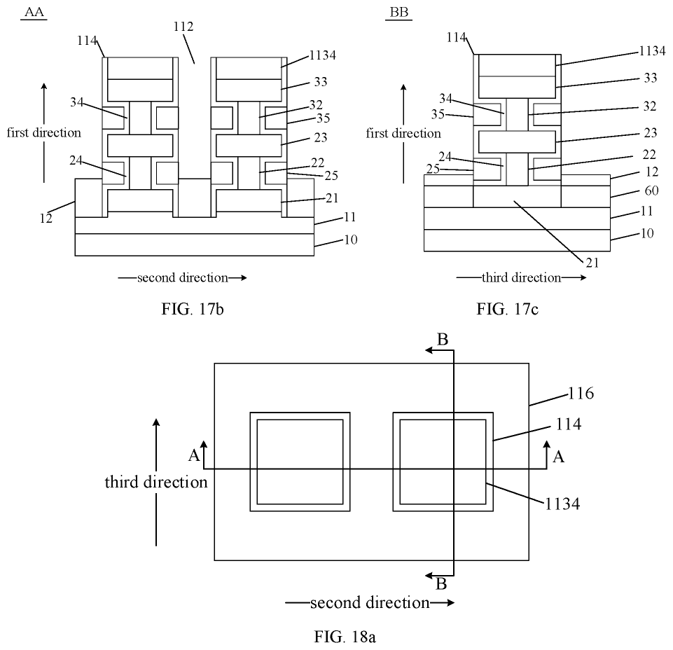

In some embodiments, a silicon oxide layer is formed on one side of the base substrate 10 by the deposition process such as the PVD, the CVD, or the ALD. The silicon oxide layer covers the bit line 60. At least a portion of the first gate 25 is exposed by an etching process, so as to form the third insulating layer 12, as shown in FIGS. 17a to 17c.

Then, the initial word line layer 116 is formed on one side of the third insulating layer 12, such that the initial word line layer 116 is connected to the first gate 25 and the second gate 35.

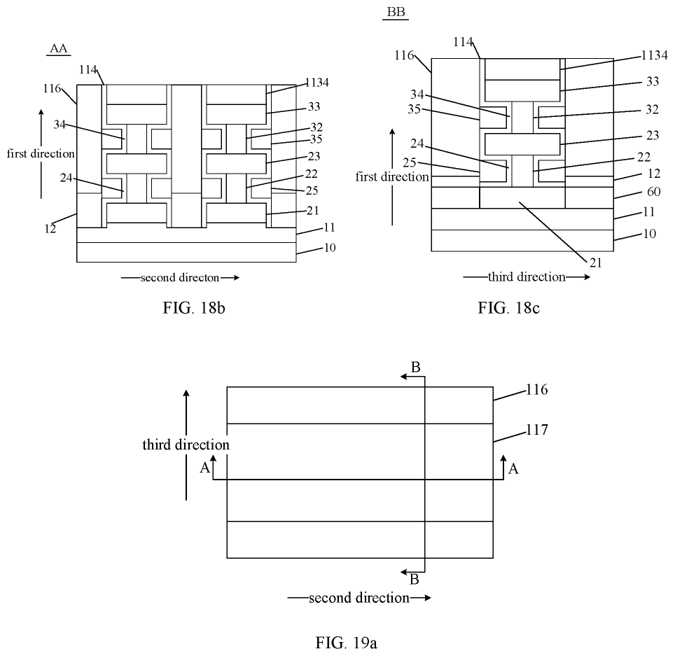

In some embodiments, an initial word line metal layer is formed on one side of the third insulating layer 12 by the deposition process such as the PVD, the CVD, or the ALD, and the initial word line metal layer is connected to the first gate 25 and the second gate 35; and the initial word line layer 116 which is flush with an upper surface of the first protection structure 1134 is acquired by treating the initial word line metal layer using the CMP process, as shown in FIG. 18a to FIG. 18c.

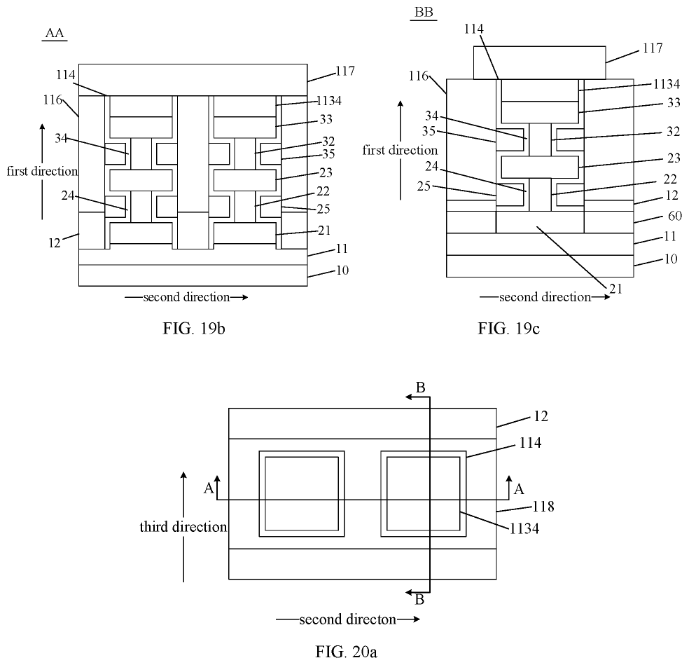

Then, the word line 50 is acquired by patterning the initial word line layer 116. The word line 50 includes a field 51. The field 51 surrounds at least a portion of first transistor 20 and at least a portion of second transistor 30. This specifically includes:
One side, away from the base substrate 10 of the initial word line layer 116 and one side, away from the base substrate 10, of the first protection structure 1134 are coated with photoresist layers, and at least two spaced third mask structures 117 are acquired by treating the photoresist layers through the process such as exposure and development, as shown in FIGS. 19a to 19c. Orthographic projections of the third mask structures 117 on the base substrate completely cover an orthographic projection of the first protection structure 1134 on the base substrate 10 and covers a portion of the initial word line layer 116.

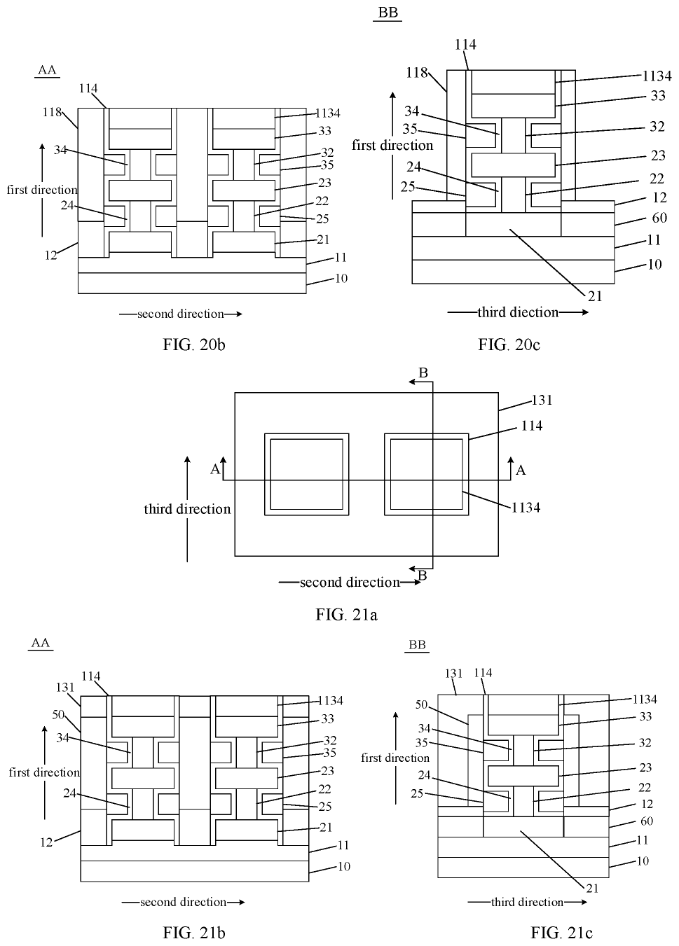

Next, a portion of the initial word line layer 116 not covered by the third mask structures 117 is etched until a portion of the third insulating layer 12 is exposed, thus acquiring an intermediate word line 118, as shown in FIGS. 20a to 20c. The intermediate word line 118 is connected to the first gate 25 and the second gate 35.

Then, the word line 50 is acquired by etching back the intermediate word line 118, such that a surface of the word line 50 is lower than a surface of the first protection structure 1134. The word line 50 is connected to the first gate 25 and the second gate 35, as shown in FIGS. 21a to 21c. In some embodiments, a surface of the word line 50 is flush with an upper surface of the second drain 33.

Next, a first sub-dielectric layer 131 covering the first transistor 20, the second transistor 30, the word line 50, and the third insulating layer 12 is formed, such that the first sub-dielectric layer 131 is flush with the surface of the first protection structure 1134, which can be achieved by the CMP process, as shown in FIGS. 20a to 21c. In some embodiments of the present disclosure, the first sub-dielectric layer 131 plays a role in insulation and planarization, which is beneficial to reduce the influence of parasitic capacitance 40 generated between a first electrode 41 of a first capacitor 40 formed later and the second transistor 30, thereby ensuring the performance of the formed memory cell.

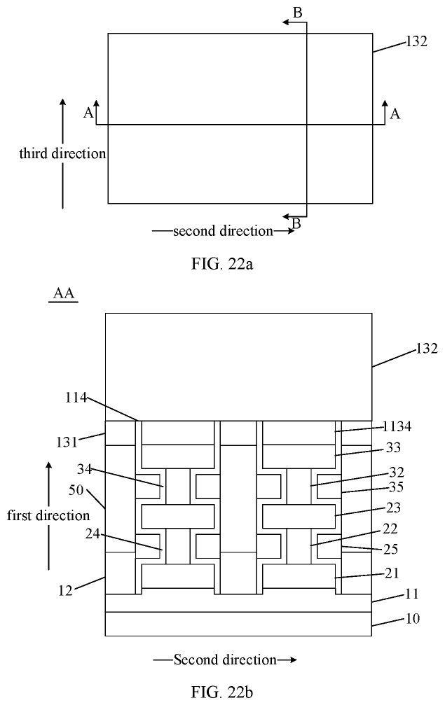

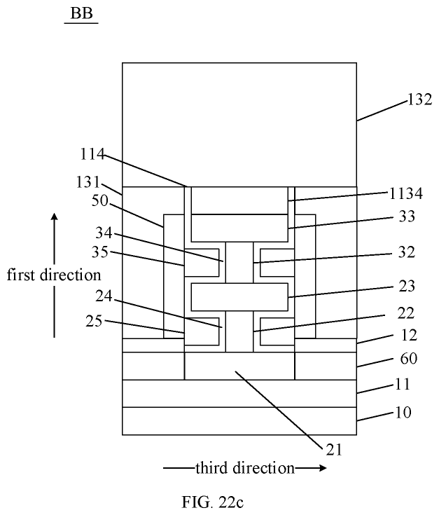

Then, a first dielectric layer 13 is acquired by forming a second sub-dielectric layer 132 on one side, away from the base substrate 10, of the first sub-dielectric layer 131, and a second intermediate substrate is acquired, as shown in FIGS. 22a to 22c.

In some embodiments of the present disclosure, in S705, forming the capacitor electrically connected to the drain on one side, away from the base substrate, of the second drain includes: acquiring a first via hole for exposing at least a portion of the second drain 33 by patterning the second intermediate substrate, and acquiring a first capacitor 40 by forming a first electrode 41, a second dielectric layer 42, and a second electrode 43 in sequence on one side of the first dielectric layer 13 and the second drain 33 in the first via hole. The step specifically includes the following steps.

Firstly, a portion of the second sub-dielectric layer 132 of the first dielectric layer 13 is etched to form the first via hole, such that at least the portion of the second drain 33 is exposed. Then, the first electrode 41 is deposited and formed in the second sub-dielectric layer 132 and the first via hole, wherein a portion of the first electrode 41 conforms to an inner wall of the first via hole. Next, the second dielectric layer 42 is formed on one side of the first electrode 41 and the second sub-dielectric layer 132, wherein a portion of the second dielectric layer 42 conforms to the first electrode 41, and the second electrode 43 is formed on one side of the second dielectric layer 42 and the second sub-dielectric layer 132, thus acquiring the first capacitor 40.

The embodiments of the present disclosure, at least achieve the following beneficial effects.

In the memory provided by the embodiments of the present disclosure, the memory cell includes the first transistor 20 and the second transistor 30 connected to the first transistor in series. Compared with a memory cell having only one transistor, the memory of the present disclosure has the advantages that a voltage difference applied to one transistor is shared by the first transistor 20 and the second transistor 30 connected in series to the first transistor, such that a drain voltage of the first transistor 20 can be significantly reduced, and a leakage current decreases exponentially as the drain voltage decreases. Therefore, the leakage current in the memory cell of the present disclosure can be reduced, and the working performance of the memory cell of the present disclosure can be ensured.

In some embodiments of the present disclosure, the common electrode 23 is only a single-layer electrode, which serves as both the first drain of the first transistor and the second source of the second transistor. The first transistor and the second transistor share the same common electrode 23, such that a thickness occupied by the first transistor and the second transistor can be reduced, which is conducive increasing a vertical stacking density of the memory cell. Moreover, the structures of the first transistor and the second transistor can be simplified, and the manufacturing process can be simplified.

Those skilled in the art can understand that various steps, measures, and schemes in the operations, methods, and procedures discussed in the present disclosure may be alternated, modified, combined, or deleted. Further, other steps, measures, and schemes in the operations, methods, and procedures discussed in the present disclosure may also be alternated, modified, rearranged, split, combined, or deleted. Further, steps, measures, and schemes in the operations, methods, and procedures disclosed in the prior art and the present disclosure may also be alternated, modified, rearranged, split, combined, or deleted.

In the descriptions of the present disclosure, directional or positional relationships indicated by the words, such as “central,” “upper,” “lower,” “front,” “rear,” “left,” “right,” “vertical,” “horizontal,” “top,” “bottom,” “inner,” “outer,” based on exemplary directional or positional relationships shown in the accompanying drawings, are merely for convenience of description or a simplified description of the embodiments of the present disclosure, and are not intended to indicate or imply that the referred apparatus or component must have a particular orientation or be constructed and operated in a particular orientation, and thus, are not to be construed as limiting the present disclosure.

The terms “first” and “second” are used for descriptive purposes only and are not to be construed as indicating or implying relative importance or to implicitly indicate the number of technical features indicated. Thus, features defined as “first,” “second,” and the like explicitly or implicitly include one or more of the features. In the descriptions of the present disclosure, “a plurality” means two or more, unless otherwise specified.

In the description of the present disclosure, it should be noted that unless otherwise explicitly specified or limited, the terms “mount,” “connect,” and “connection” shall be construed broadly and may be, for example, fixed connection, detachable connection, integrated connection, direct connection, indirect connection via an intermediate, or internal communication between two elements. For those of ordinary skill in the art, the specific meaning of the above terms in the present disclosure may be understood according to the specific condition.

In the descriptions of the specification, the specific features, structures, materials, or characteristics may be combined in any suitable manner in any one or more embodiments or examples.

It should be understood that, although the steps in the flowcharts of the accompanying drawings are shown in order as indicated by the arrows, the steps are not necessarily performed in order as indicated by the arrows. In some implementations of the embodiments of the present disclosure, the steps in the flowcharts may be performed in another order as needed, unless explicitly stated otherwise herein. Moreover, some or all of the steps in the flowcharts may include a plurality of sub-steps or a plurality of stages based on an actual implementation. Some or all of the sub-steps or stages may be performed at the same time, or may be performed at different times where the order of the sub-steps or stages may be flexibly configured as needed, which is not limited in the embodiments of the present disclosure.

Described above are some exemplary embodiments of the present disclosure. It should be noted that, for those skilled in the art, other similar implementations based on the technical concepts of the present disclosure may be adopted without departing from the technical concept of the present disclosure and are covered by the embodiments of the present disclosure.

1. A memory, comprising:
a plurality of memory cells, word lines, and bit lines,
wherein each of the memory cells comprises:
a first transistor, wherein a first source of the first transistor is electrically connected to a bit line;
a second transistor, connected in series to the first transistor; and
a capacitor, electrically connected to a second drain of the second transistor,
wherein the first transistor and the second transistor are both n-type transistors or p-type transistors, and wherein a first gate of the first transistor and a second gate of the second transistor are electrically connected to a word line.

2. The memory according to claim 1, wherein the first transistor and the second transistor are vertical transistors, and wherein the first transistor and the second transistor are stacked in a direction perpendicular to a base substrate.

3. The memory according to claim 2, wherein a common electrode is arranged between the first transistor and the second transistor in the direction perpendicular to the base substrate, wherein the first transistor is connected to the second transistor in series via the common electrode, and wherein a first drain of the first transistor and a second source of the second transistor constitute the common electrode.

4. The memory according to claim 3, wherein the first transistor comprises a first semiconductor layer, wherein the second transistor comprises a second semiconductor layer, and wherein the first semiconductor layer and the second semiconductor layer are stacked in the direction perpendicular to the base substrate.

5. The memory according to claim 4, wherein the common electrode is arranged between the first semiconductor layer and the second semiconductor layer in the direction perpendicular to the base substrate, wherein the first gate and the first semiconductor layer are arranged on a same layer, and wherein the second gate and the second semiconductor layer are arranged on a same layer.

6. The memory according to claim 5, wherein the first gate is arranged around the first semiconductor layer and is insulated from the first semiconductor layer, and wherein the second gate is arranged around the second semiconductor layer and is insulated from the second semiconductor layer.

7. The memory according to claim 5, wherein each of the first semiconductor layer, the common electrode, and the second semiconductor layer is in a columnar structure, wherein:
the first source is arranged at one end, away from the common electrode, of the first semiconductor layer or on a circumferential wall of a portion of the first semiconductor layer; and
the second drain is arranged at one end, away from the common electrode, of the second semiconductor layer or on a circumferential wall of a portion of the second semiconductor layer.

8. The memory according to claim 5, wherein orthographic projections of the first semiconductor layer and the second semiconductor layer on the base substrate are within orthographic projections of the first source, the common electrode, and the second drain on the base substrate, and
wherein orthographic projections of at least a portion of the first gate and at least a portion of the second gate on the base substrate are within the orthographic projections of the first source, the common electrode, and the second drain on the base substrate.

9. The memory according to claim 5, wherein each of the memory cells further comprises:
a connection electrode, arranged around outer sidewalls of the first gate and the second gate, wherein the first gate and the second gate are both connected to the connection electrode.

10. The memory according to claim 5, wherein each of the word lines comprises a plurality of subsections sequentially connected to each other, wherein each of the subsections is arranged around outer sidewalls of the first gate, the common electrode, the second gate and the second drain, and wherein a surface of a subsection is flush with a surface, away from the common electrode, of the second drain.

11. The memory according to claim 4, wherein the first semiconductor layer is arranged around an outer sidewall of the first gate and is insulated from the first gate, and wherein the second semiconductor layer is arranged around an outer sidewall of the second gate and is insulated from the second gate.

12. The memory according to claim 11, wherein the first gate and the second gate are integrally formed as a columnar structure,
wherein the first semiconductor layer and the second semiconductor layer are integrally formed as a cylindrical structure, and the cylindrical structure is arranged around the columnar structure, and
wherein the first source, the common electrode, and the second drain are arranged at intervals in the direction perpendicular to the base substrate and are arranged around the cylindrical structure.

13. The memory according to claim 1, wherein the capacitor is disposed on one side, away from a base substrate, of the second drain, wherein a first electrode of the capacitor is connected to the second drain.

14. A method for manufacturing a memory, comprising:
forming, by a patterning process, a plurality of repeating units spaced apart from each other on one side of a base substrate, wherein each of the repeating units comprises a first source, a first semiconductor layer, a common electrode, a second semiconductor layer, and a second drain which are stacked;
forming a first gate and a second gate on outer sidewalls of the first semiconductor layer and the second semiconductor layer respectively;
forming a bit line connected to the first source;
forming a word line connected to the first gate and the second gate; and
forming a capacitor electrically connected to the second drain on one side, away from the base substrate, of the second drain.

15. The method according to claim 14, wherein the forming, by the patterning process, the plurality of repeating units spaced apart from each other on one side of the base substrate comprises:
forming, by the patterning process, a plurality of initial repeating units spaced apart from each other on one side of the base substrate, wherein each initial repeating unit comprises the first source, a first initial semiconductor layer, the common electrode, a second initial semiconductor layer, and the second drain which are stacked; and
forming the repeating units by laterally etching the first initial semiconductor layer and the second initial semiconductor layer of initial repeating units.

16. The method according to claim 14, wherein the forming the word line connected to the first gate and the second gate comprises:
forming an initial word line layer filled between all the repeating units; and
forming the word line extending in a second direction parallel to the base substrate by patterning the initial word line layer.
